(19) United States
(12) Patent Application Publication
(10) Pub. No.: US 2026/0143865 A1
(43) Pub. Date: May 21, 2026

(54) SEMICONDUCTOR STRUCTURES, LIGHT-EMITTING DEVICES, LIGHT-EMITTING PACKAGES AND LIGHT-EMITTING SYSTEMS

(71) Applicant: EPISTAR CORPORATION, Hsinchu (TW)

(72) Inventors: Chen OU, Hsinchu (TW); Peng-Ren CHEN, Hsinchu (TW); Hao-Wei FONG, Hsinchu (TW); Chi-Ling LEE, Hsinchu (TW)

(21) Appl. No.: 18/951,835

(22) Filed: Nov. 19, 2024

(51) Int. Cl. H01L 33/08; H01L 25/16; H01L 33/04; H01L 33/22; H01L 33/32

(52) U.S. Cl. CPC H10H 20/813; H10H 20/811; H10H 20/82; H10W 90/00; H10H 20/825

(57) ABSTRACT

A semiconductor structure includes a first semiconductor stack, a tunnel junction structure and a second semiconductor stack. The first semiconductor stack includes a first first-type semiconductor layer, a first active region and a first second-type semiconductor layer. The first active region has a plurality of first recesses. The first second-type semiconductor layer conformally covers the first active region and has a plurality of second recesses corresponding to the first recesses. The tunnel junction structure conformally covers the first second-type semiconductor layer and has a plurality of third recesses corresponding to the second recesses. The second semiconductor stack is disposed on the tunnel junction structure and includes a second first-type semiconductor layer, a second active region and a second second-type semiconductor layer stacked in sequence from bottom to top. The second first-type semiconductor layer fills up the third recesses.

### BACKGROUND

### Technical Field

The present disclosure relates generally to semiconductor structures, and more particularly to semiconductor structures of light-emitting diodes.

### Description of the Related Art

The light-emitting diode (LED) is a sort of solid-state semiconductor element, which has the advantages of low power consumption, low heat generation, long lifetime, shockproof, small size, high response speed, and good optical-electrical characteristics like stable emission wavelength. Therefore, light-emitting diodes have been widely applied to household appliances, equipment indicator lights, optoelectronic products, and so forth. A dual junction light-emitting diode including a tunnel junction layer stacked between two light-emitting diodes is developed for high voltage applications. However, the current dual junction light-emitting diodes still cannot satisfy the requirements of LED chips in all aspects.

### SUMMARY

In view of this, the present disclosure provides semiconductor structures of dual or multiple junction light-emitting diodes that can reduce the series resistance and the operating voltage of LED chips and are suitable for high voltage applications.

According to an embodiment of the present disclosure, a semiconductor structure is provided and includes a first semiconductor stack, a tunnel junction structure and a second semiconductor stack. The first semiconductor stack includes a first first-type semiconductor layer, a first active region and a first second-type semiconductor layer. The first active region is disposed on the first first-type semiconductor layer and has a plurality of first recesses. The first second-type semiconductor layer conformally covers the first active region and has a plurality of second recesses corresponding to the plurality of first recesses. The tunnel junction structure conformally covers the first second-type semiconductor layer and has a plurality of third recesses corresponding to the plurality of second recesses. The second semiconductor stack is disposed on the tunnel junction structure and includes a second first-type semiconductor layer, a second active region and a second second-type semiconductor layer. The second first-type semiconductor layer fills up the plurality of third recesses. The second active region is disposed on the second first-type semiconductor layer. The second second-type semiconductor layer is disposed on the second active region.

According to an embodiment of the present disclosure, a light-emitting device is provided and includes the aforementioned semiconductor structure, a first electrode and a second electrode. The first electrode is disposed on the first first-type semiconductor layer and electrically connected to the first semiconductor stack. The second electrode is electrically connected to the second semiconductor stack.

According to an embodiment of the present disclosure, a light-emitting package is provided and includes an encapsulation substrate, a plurality of external electrodes and at least one the aforementioned light-emitting device. The external electrodes are installed on the encapsulation substrate. The light-emitting device is disposed on the encapsulation substrate and electrically connected to the external electrodes.

According to an embodiment of the present disclosure, a light-emitting system is provided and includes a light-emitting apparatus, a power module and a control module. The light-emitting apparatus includes at least one the aforementioned light-emitting package. The power module is connected to the light-emitting apparatus. The control module is connected to the power module. The power module receives an input voltage and a control signal from the control module, and provides a driving signal to the light-emitting apparatus.

According to an embodiment of the present disclosure, a light-emitting system is provided and includes a light-emitting apparatus, a power module and a control module. The light-emitting apparatus includes at least one the aforementioned light-emitting device. The power module is connected to the light-emitting apparatus. The control module is connected to the power module. The power module receives an input voltage and a control signal from the control module, and provides a driving signal to the light-emitting apparatus.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor structure according to an embodiment of the present disclosure.

FIG. 2 is a schematic cross-sectional view of a semiconductor structure according to another embodiment of the present disclosure.

FIG. 3 is a schematic cross-sectional view of a semiconductor structure according to further another embodiment of the present disclosure.

FIG. 4 is a schematic cross-sectional view of a light-emitting device according to an embodiment of the present disclosure.

FIG. 5 is a schematic cross-sectional view of a light-emitting device according to another embodiment of the present disclosure.

FIG. 6 is a schematic cross-sectional view of a light-emitting package according to an embodiment of the present disclosure.

FIG. 7 is a schematic cross-sectional view of a light-emitting package according to another embodiment of the present disclosure.

FIG. 8 is a schematic view of a light-emitting apparatus 2 disclosed in an embodiment of the present disclosure.

FIG. 9 is a schematic function block view of a light-emitting system according to some embodiments of the present disclosure.

### DETAILED DESCRIPTION OF THE EMBODIMENTS

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the semiconductor structure in use or operation in addition to the orientation depicted in the figures. For example, if the semiconductor structure in the figures is turned over, elements described as “below” and/or “beneath” other elements or features would then be oriented “above” and/or “over” the other elements or features. The semiconductor structures may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

In the present disclosure, if not specifically mention, the general expression of AlGaN means AlₐGa₍₁₋ₐ₎N, wherein 0≤a≤1; the general expression of InGaN means In_{b}Ga_{(1-b)}N, wherein 0≤b≤1; the general expression of AlInGaN means AlcIndGa_{(1-c-d)}N, wherein 0≤c≤1, 0≤d≤1; the general expression of AlInGaP means AleInfGa_{(1-e-f)}P, wherein 0≤e≤1, 0≤f≤1; and the general expression of InGaAsP means In_{g}Ga_{(1-g)}AsₕP₍₁₋ₕ₎, wherein 0≤g≤1, 0≤h≤1. The content of the element may be adjusted for different purposes, such as, but not limited to, adjusting the energy gap or the peak wavelength of the light emitted from semiconductor stacks.

The compositions and dopants of each layer in the semiconductor stacks of the present disclosure may be determined by any suitable means, such as secondary ion mass spectrometer (SIMS).

The thickness of each layer in the semiconductor stacks disclosed in the present disclosure may be analyzed by suitable means, such as transmission electron microscopy (TEM) or scanning electron microscope (SEM), thereby corresponding to, for example, the depth position of each layer on the SIMS map.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to semiconductor structures of multiple junction light-emitting diodes such as dual junction light-emitting diodes or three junction light-emitting diodes. The semiconductor structure includes a tunnel junction structure stacked between two semiconductor stacks. Moreover, the tunnel junction structure conformally covers a plurality of recesses on a top surface of a lower semiconductor stack, so that carriers injected from an upper semiconductor stack may enter the lower semiconductor stack through a shorter path. Therefore, the series resistance and the operating voltage of an LED chip using the semiconductor structure are reduced.

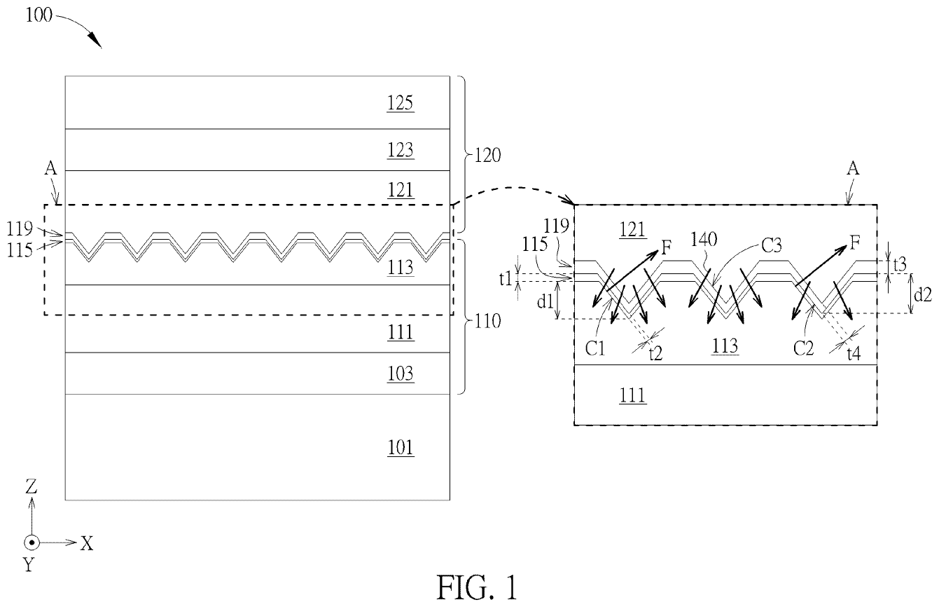

FIG. 1 shows a schematic cross-sectional view of a semiconductor structure 100 according to an embodiment of the present disclosure. The semiconductor structure 100 includes a first semiconductor stack 110, a tunnel junction structure 119 and a second semiconductor stack 120 stacked in sequence from bottom to top. In one embodiment, the first semiconductor stack 110 may be formed on a growth substrate 101 by epitaxial growth. The growth substrate 101 may include a sapphire (Al2O3) substrate, a gallium nitride (GaN) substrate, a silicon carbide (SiC) substrate, a silicon (Si) substrate or an aluminum nitride (AlN) substrate. In one embodiment, the growth substrate 101 may be a patterned substrate, that is, a surface of the growth substrate 101 on which the first semiconductor stack 110 is formed may have a patterned structure.

In some embodiments of the present disclosure, the method for processing epitaxial growth may include metal organic chemical vapor deposition (MOCVD), hydride vapor deposition (HVPE), molecular beam epitaxy (MBE), physical vapor deposition (PVD) or liquid-phase epitaxy (LPE) method, but is not limited thereto. MOCVD epitaxial growth method will be used for representative description in the following embodiments.

The first semiconductor stack 110 includes a semiconductor light-emitting stack constituting a light-emitting element such as a light-emitting diode or a laser. Referring to FIG. 1, the first semiconductor stack 110 includes a first first-type semiconductor layer 111, a first active region 113 and a first second-type semiconductor layer 115 stacked in sequence from bottom to top. In the following embodiments, the first-type semiconductor layer may be the semiconductor layer including a first conductivity-type such as n-type, and the second-type semiconductor layer may be the semiconductor layer including a second conductivity-type such as p-type. By changing the physical and chemical composition of one or more layers, such as the first active region 113, of the first semiconductor stack 110, the wavelength of the emitted light thereof can be adjusted. The first first-type semiconductor layer 111, the first active region 113 and the first second-type semiconductor layer 115 may include the same series of III-V semiconductor materials, such as InGaN series materials, AlGaN series materials or AlInGaN series materials. When the material of the first active region 113 includes InGaN series materials, a blue light with a wavelength between 400 nm and 490 nm, a cyan light with a wavelength between 490 nm and 530 nm, or a green light with a wavelength between 530 nm and 570 nm can be emitted from the first active region 113. When the material of the first active region 113 includes AlGaN series or AlInGaN series materials, an ultraviolet light with a wavelength between 250 nm and 400 nm can be emitted from the first active region 113. In one embodiment, the first active region 113 may include a single heterostructure, a double heterostructure, or a multiple quantum well. The first active region 113 includes multiple barrier layers and multiple well layers stacked alternately. In one embodiment, the materials of the first active region 113 may be i-type, p-type or n-type semiconductors.

In one embodiment, the material of the first first-type semiconductor layer 111 includes AlₐGa₍₁₋ₐ₎N, wherein 0≤a≤1. The material of the first first-type semiconductor layer 111 may be doped with a first conductivity-type dopant. In one embodiment, the concentration of the first conductivity-type dopant of the first first-type semiconductor layer 111 is greater than 1×10¹⁸/cm³, for example, greater than 1×10¹⁹/cm³, or between 1×10¹⁹/cm³ and 9×10¹⁹/cm³ (two endpoints included).

In one embodiment, the first semiconductor stack 110 may further include other layers between the first first-type semiconductor layer 111 and the first active region 113. For example, in order to reduce lattice mismatch between the growth substrate 101 and the first active region 113, a buffer structure 103 may be formed between the growth substrate 101 and the first first-type semiconductor layer 111, and/or a stress-releasing structure (not shown) may be further formed between the first first-type semiconductor layer 111 and the first active region 113. Details of the buffer structure 103 will be described latter. The stress releasing layer may be a superlattice structure alternately stacked by two semiconductor layers composed of different materials. The two semiconductor layers are, for example, indium gallium nitride (InGaN) layer and gallium nitride (GaN) layer, or aluminum gallium nitride (AlGaN) layer and gallium nitride (GaN) layer. The stress-releasing layer may also be formed by a semiconductor stack including multiple layers having the same effect and different composed materials, such as a graduated multilayer structure composed by group III-V elements. In order to reduce operating voltage (Vf) and enhance anti-electrostatic discharge (anti-ESD) capability of the first semiconductor stack 110, the first semiconductor stack 110 may include a low doping layer between the first first-type semiconductor layer 111 and the stress-releasing structure to enhance the current spreading in the first first-type semiconductor layer 111, or prevent the first semiconductor stack 110 from being damaged by surges.

In one embodiment, the first semiconductor stack 110 may further include a hole blocking region in the stress-releasing structure, or between the stress-releasing structure and the active region 113. In one embodiment, the first semiconductor stack 110 may further include an electron blocking region (not shown) between the first active region 113 and the first second-type semiconductor layer 115. The hole blocking region and the electron blocking region can prevent the carriers such as holes and electrons to escape from the first active region 113 without electron-hole recombination. The electron blocking region has a higher energy band gap than that of the barrier layers in the first active region 113. The electron blocking region may include a single layer, a plurality of sublayers, or a plurality of alternating first sublayers and second sublayers. In one embodiment, a plurality of alternating first sublayers and second sublayers form a superlattice structure. In one embodiment, the electron blocking region may be doped or unintentionally doped. The electron blocking region includes the second conductivity-type dopant, and the second conductivity-type dopant concentration is greater than 1×10¹⁷/cm³ and/or not greater than 1×10²¹/cm³. In one embodiment, the electron blocking region includes co-doping the first conductivity-type dopant and the second conductivity-type dopant, and the first conductivity-type dopant concentration is greater than 3×10¹⁷/cm³ and/or not greater than 3×10¹⁸/cm³, the second conductivity-type dopant concentration is greater than 2×10¹⁹/cm³ and/or not greater than 1.5×10²⁰/cm³. The hole blocking region includes the first conductivity-type dopant, and the first conductivity-type dopant concentration is greater than 1×10¹⁷/cm³ and/or not greater than 1×10²¹/cm³. In specific, the first conductivity-type dopant concentration of the hole-blocking layer may be greater than those of the stress-releasing structure and the active region 113.

In one embodiment, the first second-type semiconductor layer 115 includes Al_{g}Ga_{(1-g)}N, wherein 0≤g≤1. In one embodiment, the dopant concentration of the second conductivity-type dopant in the first second-type semiconductor layer 115 is greater than 1×10¹⁸/cm³, for example, greater than 1×10¹⁹/cm³. In some embodiments, the first second-type semiconductor layer 115 includes a multilayer structure, such as a superlattice structure. By adjusting the dopant concentration or the gradience of composed materials of the multilayer structure, the epitaxial quality of the first second-type semiconductor layer 115 can be improved. In one embodiment, one or more layers other than the electron blocking region may be disposed between the first active region 113 and the first second-type semiconductor layer 115. For example, a diffusion prevention layer (not shown) may be disposed between the electron blocking region and the first active region 113. The diffusion prevention layer is used to prevent the second conductivity-type dopant of first second-type semiconductor layer 115 or of the electron blocking region from diffusing into the first active region 113. The deterioration of epitaxial quality or efficiency in the first active region 113 can be avoided accordingly.

In one embodiment, before forming the first semiconductor stack 110, the buffer structure 103 may be formed on the growth substrate 101. The buffer structure 103 can reduce the dislocation caused by the lattice mismatch between the growth substrate 101 and the first semiconductor stack 110 to improve the epitaxy quality. The buffer structure 103 may contain a single layer or multiple layers. In one embodiment, the buffer structure 103 includes AliGa(1−i)N, wherein 0≤i≤1. In one embodiment, the material of the buffer structure 103 includes GaN. In another embodiment, the material of the buffer structure 103 includes AlN. The method for forming the buffer structure 103 may be MOCVD, MBE, HVPE or PVD. The PVD includes sputtering or electron beam evaporation. When the buffer structure 103 includes multiple sublayers (not shown), the sublayers include the same material or different materials. In one embodiment, the buffer structure 103 includes two sublayers, wherein a first sublayer is formed by sputtering, and a second sublayer is grown by MOCVD. In one embodiment, the buffer structure 103 further includes a third sublayer. The third sublayer is grown by MOCVD, and a growth temperature of the second sublayer may be higher or lower than a growth temperature of the third sublayer. In one embodiment, the first, second and third sub-layers include the same material, such as AlN, or a combination of different materials, such as AlN, GaN and AlGaN. In another embodiment, the buffer structure 103 may be a PVD-AlN layer, and a target of the PVD used to form PVD-AlN layer is composed of aluminum nitride, or using an aluminum metal target in a nitrogen-source environment to reactively form the PVD-AlN layer. In one embodiment, the buffer structure 103 may be undoped, i.e., not intentionally doped. In another embodiment, the buffer structure 103 may include a dopant such as silicon, carbon, hydrogen, oxygen or a combination thereof, and the concentration of this dopant in the buffer structure 103 is not less than 1×10¹⁷/cm³.

The semiconductor structure 100 includes the second semiconductor stack 120 disposed on the first semiconductor stack 110. The second semiconductor stack 120 also includes a semiconductor light-emitting stack constituting a light-emitting element such as a light-emitting diode or a laser. The second semiconductor stack 120 includes a second first-type semiconductor layer 121, a second active region 123 and a second second-type semiconductor layer 125 stacked in sequence from bottom to top. By changing the physical and chemical composition of one or more layers, such as the second active region 123, of the second semiconductor stack 120, the wavelength of the emitted light thereof can be adjusted. The second first-type semiconductor layer 121, the second active region 123 and the second second-type semiconductor layer 125 may include the same series of III-V semiconductor materials, such as InGaN series materials, AlGaN series materials or AlInGaN series materials. The second semiconductor stack 120 and the first semiconductor stack 110 may have similar layers, for example, the details of the materials of the second first-type semiconductor layer 121, the second active region 123, the second second-type semiconductor layer 125 may refer to the aforementioned descriptions of the first first-type semiconductor layer 111, the first active region 113 and the first second-type semiconductor layer 115, and are not repeated herein. Moreover, similar to the first semiconductor stack 110, the second semiconductor stack 120 may include the electron-blocking layer and the stress-releasing layer. However, the second semiconductor stack 120 may not include the buffer structure.

Furthermore, the materials of one or more layers in the first semiconductor stack 110 may be the same as or different from the materials of one or more layers in the second semiconductor stack 120. In one embodiment, a contact layer including the first conductivity-type dopant, such as Si, may be formed on the second second-type semiconductor layer 125 to form an ohmic contact with an electrode of a light-emitting device. The dopant concentration of the second conductivity-type dopant of the second second-type semiconductor layer 125 may be greater than or less than that of the first conductivity-type dopant of the contact layer 125.

The tunnel junction structure 119, interposed between the first semiconductor stack 110 and the second semiconductor stack 120, allows current flow through reverse-biased p-n junction between the first second-type semiconductor layer 115 and the second first-type semiconductor layer 121. This is achieved by suitable heavy doping to align the valence and conduction bands of neighboring layers to allow two-way tunneling of electrons and holes through a very thin depletion region. In one embodiment, the tunnel junction structure 119 includes a heavily doped second-type semiconductor layer (not shown) in direct contact with the first second-type semiconductor layer 115, and a heavily doped first-type semiconductor layer (not shown) in direct contact with the second first-type semiconductor layer 121. In some embodiments, the tunnel junction structure 119 may include p+−GaN, n−InGaN and n+−GaN, or p+−AlGaN and n+−AlGaN, or p+−AlGaN, InGaN and n+−AlGaN stacked in sequence from bottom to top.

Referring to FIG. 1, an enlarged view of an area A in the semiconductor structure 100 is shown. The first active region 113 is disposed on the first first-type semiconductor layer 111 and has a plurality of first recesses C1. Some of the first recesses C1 each has an opening on the top surface of the first active region 113 and a bottom located in the first active region 113. The first recesses C1 may include pits or trenches. In one embodiment, in a cross-sectional view, each of the pits may be V-shape, and in a top view, the shape of the pit may be hexagon. In one embodiment, in a cross-sectional view, each of the trenches may be a V-shape. The first recesses C1 may be formed by nature epitaxial growth or etching a portion of the first active region 113. When the first active region 113 is epitaxially grown, the opening size of the first recess C1 gradually increases with the growth direction. In one embodiment, during epitaxial growth of the semiconductor structure 100, defects (not shown) may be induced in the stress-releasing structure and/or a low-doping semiconductor layer (not shown) between the stress-releasing structure and the first first-type semiconductor layer 111, and gradually increase in size with subsequent epitaxial growth. Subsequent epitaxial layers will partially fill in the defects, and the unfilled defects constitute the first recesses C1. In one embodiment, the barrier layers and the well layers are fill in the defects. After growing the last barrier layer or the last well layer, the first recesses C1 are formed. The first recesses C1 include V-shaped pits. The distribution density of the first recesses C1 in the first active region 113 may be between 1−2×10⁸/cm². In a cross-sectional view, one of the first recesses C1 may have an opening width between 240-280 nm.

Due to intrinsic physical limitations, in the first active region 113, most electrons and holes recombine near the first second-type semiconductor layer 115. In one embodiment, one or all of the well layers and one or all of the barrier layers in the defects has an inclined surface. The first recess C1 has an inclined surface which is the top surface of the last barrier layer or the last well layer. The thicknesses of the barrier layers and the well layers in the defects are thinner than those on the planes outside of the defects. For example, when the growth substrate is a sapphire substrate, the surface for epitaxial growth of the growth substrate includes a polar plane, such as C-plane, and the inclined surface of the first recess C1 includes a semi-polar plane, thereby making holes inject into the first active region 113 more easily via the inclined surface. Therefore, the injection of holes can be increased to increase electron-hole recombination rate, thereby improving the light-emitting efficiency. In addition, the current spreading can be improved by the first recess C1 and then the anti-electrostatic discharge (anti-ESD) capability of the first semiconductor stack 110 can be enhanced.

Referring to FIG. 1, the first second-type semiconductor layer 115 conformally covers the first active region 113 and has a plurality of second recesses C2 corresponding to the first recesses C1. In the embodiment, the first second-type semiconductor layer 115 has a top surface and a bottom surface. Both of the top surface and the bottom surface of the first second-type semiconductor layer 115 extend along the top surface of the first active region 113 and the inclined surface of the first recesses C1. The normal directions of the top surface and the bottom surface on the inclined surface of the first recesses C1 are parallel to the normal direction F of the inclined surface. In other words, the first recesses C1 are not filled up by the first second-type semiconductor layer 115. The second recess C2 has a shape in which the first recess C1 is covered by the first second-type semiconductor layer 115. In order to achieve above configuration, the first second-type semiconductor layer 115 is thinner than the depth of the first recesses C1 formed therebelow. In one embodiment, the thickness of the second second-type semiconductor layer 125 may be greater than the thickness of the first second-type semiconductor layer 115. Also, the tunnel junction structure 119 conformally covers the first second-type semiconductor layer 115 and has a plurality of third recesses C3 corresponding to the second recesses C2. In the embodiment, the tunnel junction structure 119 has a top surface and a bottom surface. Both of the top surface and the bottom surface of the tunnel junction structure 119 extend along the top surface of the first second-type semiconductor layer 115 and the inclined surface of the second recesses C2. The normal directions of the top surface and the bottom surface of the first second-type semiconductor layer 115 on the inclined surface of the second recesses C2 are parallel to the normal direction of the inclined surface of the second recesses C2, or parallel to the normal direction F of the inclined surface. In other words, the second recesses C2 are not filled up by the tunnel junction structure 119. The third recess C3 has a shape in which the second recess C2 is covered by the tunnel junction structure 119. In one embodiment, the first recesses C1, the second recesses C2 and the third recesses C3 have the same shapes. The first recesses C1, the second recesses C2 and the third recesses C3 all may be V-shaped recesses with a V shape in the cross-sectional view of FIG. 1. Each of the first recess C1, the second recess C2 and the third recess C3 may be a hexagonal conical recess, and the bottom thereof has a pointed bottom in the cross-sectional view. In addition, the second first-type semiconductor layer 121 may fill up the third recesses C3 and has a flat surface facing the second active region 123.

Moreover, referring to FIG. 1, in a first direction such as the Z-axis direction, the first recess C1 has a first depth d1 and the first second-type semiconductor layer 115 has a first thickness t1 on the substantially flat top surface of the first active region 113. The first second-type semiconductor layer 115 further has a second thickness t2 on the inclined surface of the first recess C1. In one embodiment, the first depth d1 is greater than the first thickness t1 and the second thickness t2. In one embodiment, the first thickness t1 is greater than the second thickness t2, i.e., d1>t1>t2. The portions of the first second-type semiconductor layer 115 in the first recesses C1 provides a short path 140 for carriers, such as holes, to pass through and then into the first active region 113. In some embodiments, the first depth d1 is between about 1000Å and about 3000Å, for example about 2000Å. In some embodiments, the first thickness t1 and the second thickness t2 of the first second-type semiconductor layer 115 both are less than 2000Å, for example between about 400Å and about 2000Å. Also, in the first direction, the second recess C2 has a second depth d2, and the tunnel junction structure 119 has a third thickness t3 on the substantially flat top surface of the first second-type semiconductor layer 115. The tunnel junction structure 119 further has a fourth thickness t4 on the inclined surface of the second recess C2. The second depth d2 is greater than the third thickness t3, and the third thickness t3 is greater than the fourth thickness t4, i.e., d2>t3>t4. The portions of the tunnel junction structure 119 in the second recesses C2 provides a short path 140 for carriers to pass through and then into the second first-type semiconductor layer 121. The tunnel junction structure 119 may include a junction for converting electrons into holes. In some embodiments, the third thickness t3 and the fourth thickness t4 of the tunnel junction structure 119 both are between about 50Å and about 500Å, for example about 200Å. In some embodiments, the second depth d2 is between about 1000Å and about 3000Å, for example about 2000Å. The third recesses C3 are filled up by the second first-type semiconductor layer 121, and a thickness of the second first-type semiconductor layer 121 is greater than a depth of the third recesses C3.

Accordingly, the thinner second thickness t2 of the first second-type semiconductor layer 115 in the first recess C1 and the thinner fourth thickness t4 of the tunnel junction structure 119 in the second recess C2 provide a short path 140 for carriers to pass through. Therefore, the series resistance (Rs) between the first semiconductor stack 110 and the second semiconductor stack 120 can be reduced, and the operating voltage (Vf) of a light emitting device including the semiconductor structure 100 is also reduced. Moreover, the light-emitting efficiency of the light emitting device is enhanced.

In a comparative example, a first second-type semiconductor layer is formed on the first active region 113 to fill up the first recesses C1 and with a thickness. Since in the comparative example the first recesses C1 is filled up by the first second-type semiconductor layer, an upper surface of the first second-type semiconductor layer is flat, and a tunnel junction structure on the first second-type semiconductor layer also includes a flat upper surface. Therefore, the semiconductor structure of the comparative example does not have the second recesses C2 and the third recesses C3.

In the present embodiment, the first second-type semiconductor layer 115 is conformally formed on the top surface of the first active region 113 and in the first recesses C1 to have the second recesses C2. Also, the tunnel junction structure 119 is conformally formed on the top surface of the first second-type semiconductor layer 115 and in the second recesses C2 to have the third recesses C3. The thin portions of the first second-type semiconductor layer 115 in the first recesses C1 and the thin portions of the tunnel junction structure 119 in the second recesses C2 provide a shorter path 140 for carriers injected from the second first-type semiconductor layer 121 entering the first active region 113 than in the comparative example. Therefore, the series resistance (Rs) of the present embodiment is lower than that of the comparative example by about 40%, and the operating voltage (Vf) of the present embodiment is lower than that of the comparative example by about 35%. Moreover, compared with two single-junction LED chips connected in series and under the same operating voltage, the brightness of an LED chip with the semiconductor structure of the present embodiment is also improved by about 45% to 55%.

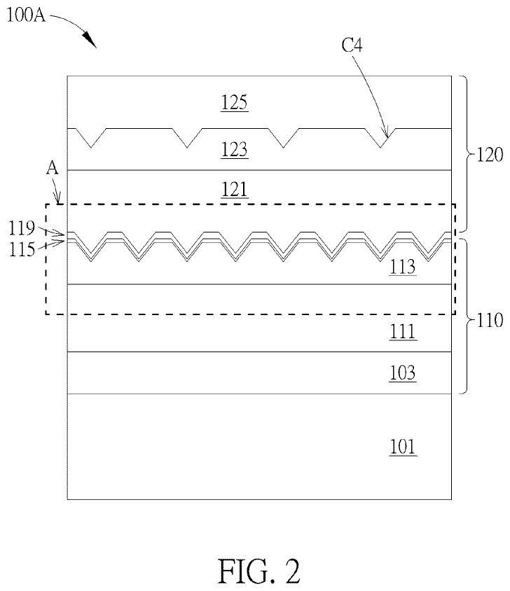

FIG. 2 shows a schematic cross-sectional view of a semiconductor structure 100A according to another embodiment of the present disclosure. The semiconductor structure 100A can be similar to the semiconductor structure 100 of FIG. 1. A difference between them is that the second active region 123 of the semiconductor structure 100A further has a plurality of fourth recesses C4. In one embodiment, similar to the first recesses C1, each of the fourth recesses C4 may have a V shape in a cross-sectional view. The method of forming the fourth recesses C4, and the shape of the fourth recesses C4 are similar as described above. In the embodiment, the fourth recesses C4 are induced by defects when the second active region 123 is epitaxially grown. The fourth recess C4 includes a hexagonal conical recess, and the bottom thereof has a pointed bottom in a cross-sectional view. Each of the fourth recesses C4 has an opening on the top surface of the second active region 123 and a bottom located in the second active region 123. The opening size of the fourth recess C4 gradually increases along the growth direction. The second second-type semiconductor layer 125 fills up the fourth recesses C4 and has a flat top surface or a roughening surface. The thickness of the second second-type semiconductor layer 125 is greater than the thickness of the first second-type semiconductor layer 115.

In one embodiment, the number of the fourth recesses C4 is less than the number of the first recesses C1. Moreover, in the first direction such as the Z-axis direction, the depth of one of the fourth recesses C4 may be smaller than, equal to, or greater than the depth d1 of one of the first recesses C1. Other functions and advantages of the fourth recesses C4 may refer to the aforementioned description of the first recesses C1. In addition, the details of other features and the area A of the semiconductor structure 100A in FIG. 2 may refer to the aforementioned description of the semiconductor structure 100 in FIG. 1, and are not repeated herein.

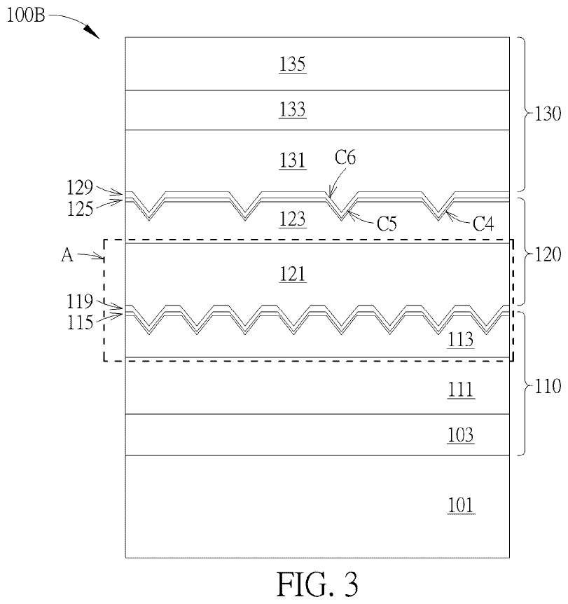

FIG. 3 shows a schematic cross-sectional view of a semiconductor structure 100B according to further another embodiment of the present disclosure. The semiconductor structure 100B of FIG. 3 further includes a third semiconductor stack 130 disposed on the second semiconductor stack 120, and an additional tunnel junction structure 129 disposed between the third semiconductor stack 130 and the second semiconductor stack 120. The third semiconductor stack 130 also includes a semiconductor light-emitting stack constituting a light-emitting element such as a light-emitting diode or a laser. The third semiconductor stack 130 includes a third first-type semiconductor layer 131, a third active region 133 and a third second-type semiconductor layer 135 stacked in sequence from bottom to top. In addition, the second second-type semiconductor layer 125 conformally covers the second active region 123 and has a plurality of fifth recesses C5 corresponding to the fourth recesses C4. Also, the tunnel junction structure 129 conformally covers the second second-type semiconductor layer 125 and having a plurality of sixth recesses C6 corresponding to the fifth recesses C5. The third first-type semiconductor layer 131 fills up the sixth recesses C6 and has a flat top surface adjacent to the third active region 133. In one embodiment, the thickness of the second second-type semiconductor layer 125 is less than 2000Å. The thickness of the tunnel junction structure 129 is less than 500Å. In addition, the details of other features and the area A of the semiconductor structure 100B in FIG. 3 may refer to the aforementioned descriptions of the semiconductor structures 100 in FIG. 1, and are not repeated herein. In one embodiment, the second active region 123 may not include the fourth recesses C4, thereby the second second-type semiconductor layer 125 may not include the fifth recesses C5, and the tunnel junction structure 129 may not include the sixth recesses C6.

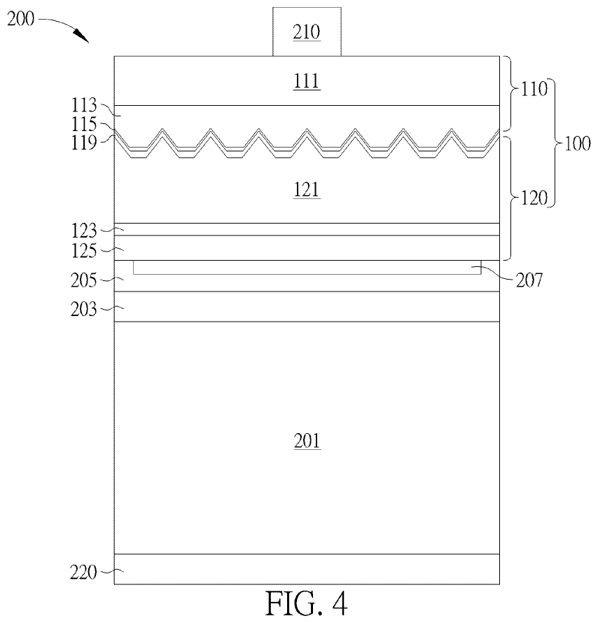

FIG. 4 shows a schematic cross-sectional view of a light-emitting device 200 according to an embodiment of the present disclosure. The light-emitting device 200 of FIG. 4 is a vertical-type LED chip. The light-emitting device 200 may include a conductive substrate 201, a second electrode 220, and the aforementioned first semiconductor stack 110 and the second semiconductor stack 120 of semiconductor structure 100 of FIG. 1. But is not limited thereto, the light-emitting device 200 may also include the semiconductor structure of FIG. 2 or FIG. 3. The second electrode 220 and the semiconductor structure 100 are respectively disposed on opposite sides of the conductive substrate 201. In one embodiment, the first semiconductor stack 110 and the second semiconductor stack 120 originally grown on the growth substrate 101 can be transferred and bonded to the conductive substrate 201, and then the growth substrate 101 can be removed to expose a surface of the second semiconductor stack 120. The second electrode 220 is disposed under the conductive substrate 201 and electrically connected to the second semiconductor stack 120. Moreover, referring to FIG. 1, the first semiconductor stack 110 includes the first recesses C1. Each of the first recesses C1 has an opening on the top surface of the first active region 113. In this embodiment, the openings of the first recesses C1 face to the conductive substrate 201.

The light-emitting device 200 may further include a first electrode 210, a reflective layer 207 and a barrier layer 205. The materials of the reflective layer 207 and the barrier layer 205 include different metals. The first electrode 210 may be disposed on a top surface of the semiconductor structure 100. In this embodiment, the first electrode 210 is disposed on a surface of the first first-type semiconductor layer 111 and electrically connected to the first semiconductor stack 110. The reflective layer 207 may be disposed on a bottom surface of the semiconductor structure 100. The barrier layer 205 may be disposed under the reflective layer 207 and cover the reflective layer 207. In this embodiment, the reflective layer 207 is disposed between the barrier layer 205 and the second second-type semiconductor layer 125 of the second semiconductor stack 120.

The light-emitting device 200 may further include a bonding layer 203 disposed between the conductive substrate 201 and the semiconductor structure 100. In this embodiment, the bonding layer 203 may connect the conductive substrate 201 and the second semiconductor stack 120. Moreover, the bonding layer 203 is disposed between the barrier layer 205 and the conductive substrate 201. The barrier layer 205 is disposed between the bonding layer 203 and the second semiconductor stack 120. Moreover, the barrier layer 205 is disposed between the bonding layer 203 and the reflective layer 207. The barrier layer 205 may be able to prevent the materials of the bonding layer 203 from diffusing into the reflective layer 207 during the manufacturing process. The diffused materials of the bonding layer 203 may be reacted with the reflective layer 207 to form a compound or alloy affecting the reflectivity and conductivity of the reflective layer 207.

The reflective layer 207 may include metal material such as silver (Ag), gold (Au), aluminum (Al), titanium (Ti), chromium (Cr), copper (Cu), nickel (Ni), platinum (Pt), ruthenium (Ru), tungsten (W), rhodium (Rh) or an alloy or a stack of the above materials. In an embodiment, the reflective layer 207 may include a multi-layer structure (not shown), for example, the reflective layer 207 may include a multi-layer structure stacked by a first metal layer, a second metal layer and a third metal layer. The first metal layer, the second metal layer and the third metal layer are stacked in sequence. The first metal layer may include silver (Ag), the second metal layer may include titanium tungsten (TiW), and the third metal layer may include platinum (Pt). The reflective layer 207 may form an ohmic contact with the second semiconductor structure 150.

The barrier 205 may include metal materials such as aluminum (Al), chromium (Cr), platinum (Pt), titanium (Ti), tungsten (W), zinc (Zn), or an alloy or a stack including above materials. In an embodiment, when the barrier 205 is a metal stack, the barrier 205 is alternately stacked by two or more metal layers, such as Cr/Pt, Cr/Ti, Cr/TiW, Cr/W, Cr/Zn, Ti/Pt, Ti/W, Ti/TiW, Ti/Zn, Pt/TiW, Pt/W, Pt/Zn, TiW/W, TiW/Zn, or W/Zn.

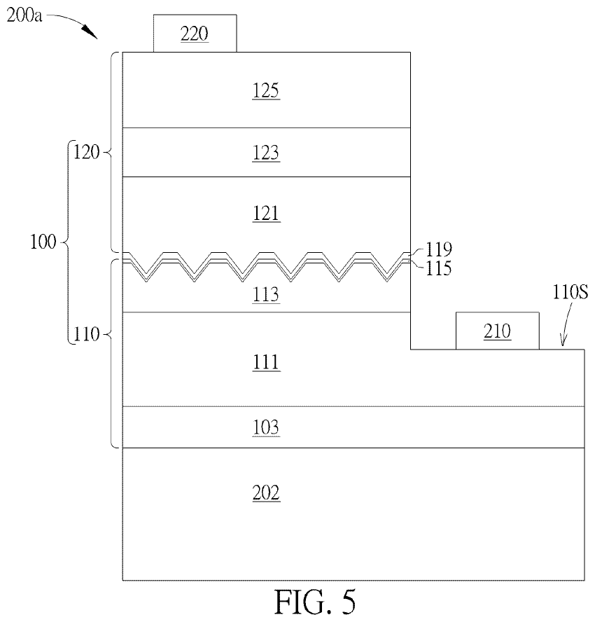

FIG. 5 shows a schematic cross-sectional view of a light-emitting device 200a according to another embodiment of the present disclosure. The light-emitting device 200a of FIG. 5 is a lateral LED chip. The light-emitting device 200a includes a carrier substrate 202 and the aforementioned semiconductor structure 100 on the carrier substrate 202. The carrier substrate 202 supports the semiconductor structure 100. In one embodiment, the carrier substrate 202 is a growth substrate used as epitaxial growth of the semiconductor structure 100. The carrier substrate 202 may be an insulating substrate. The carrier substrate 202 can be disposed under the first first-type semiconductor layer 111. In another embodiment, an insulating adhesive layer (not shown) is disposed between the semiconductor structure 100 and the carrier substrate 202, wherein the semiconductor structure 100 is grown on an epitaxial substrate (not shown) at first, and then mounted on the carrier substrate 202 through at least one transfer process. According to the number of transfer process, the carrier substrate 202 may be disposed under the first semiconductor stack 110 or the second semiconductor stack 120. Referring to FIG. 1, the first semiconductor stack 110 includes the first recesses C1. Each of the first recesses C1 has an opening on the top surface of the first active region 113. In this embodiment, the bottom of the first recess C1 is closer to the carrier substrate 202 than the opening thereof. The first first-type semiconductor layer 111 of the first semiconductor stack 110 has an exposed surface 110S not covered by a stacked structure including the first active region 113, the first second-type semiconductor layer 115, the tunnel junction structure 119 and the second semiconductor stack 120.

The light-emitting device 200a further includes a first electrode 210 and a second electrode 220. The first electrode 210 is located on the exposed surface 110S and electrically connected to the first first-type semiconductor layer 111. The second electrode 220 is located on and electrically connected to the second second-type semiconductor layer 125 of the second semiconductor stack 120. In one embodiment, a transparent conductive layer (not shown) may be disposed between the second electrode 220 and the second second-type semiconductor layer 125.

In one embodiment, the carrier substrate 202 may be a patterned substrate, that is, the carrier substrate 202 has a patterned structure (not shown) on a surface where the first semiconductor stack 110 is located. The light emitted from the semiconductor structure 100 may be refracted and/or reflected by the patterned structure of the carrier substrate 202, thereby improving the brightness of the light-emitting device 200a.

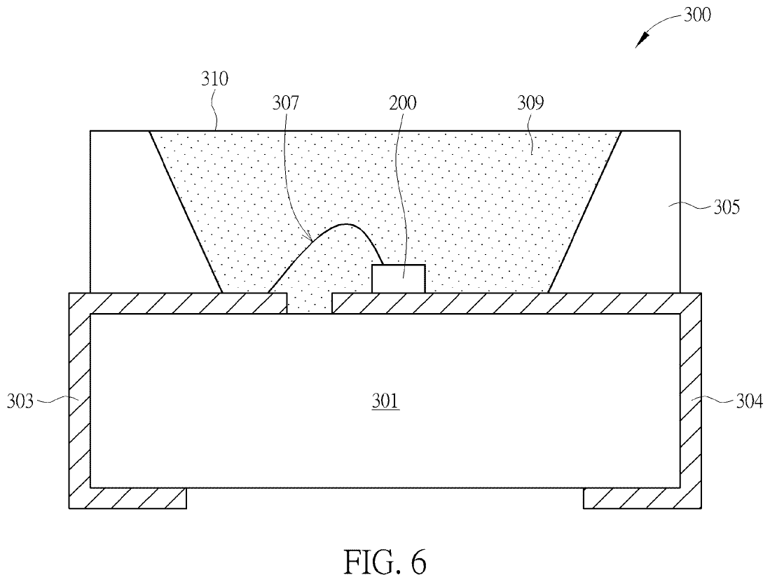

FIG. 6 shows a schematic cross-sectional view of a light-emitting package 300 according to an embodiment of the present disclosure. The light-emitting package 300 may include an encapsulation wall 305, an encapsulation substrate 301, a plurality of terminals 303 and 304 installed on the encapsulation substrate 301, at least one light-emitting device 200 of FIG. 4 on the encapsulation substrate 301, installed in the encapsulation wall 305 and electrically connected to the terminals 303 and 304, and a packaging material 310 including wavelength conversion material 309, such as phosphor, 309 to surround the light-emitting device 200. The external electrodes 303 and 304 are electrically insulated from each other, and provide power to the light-emitting device 200 by wire 307. In addition, the terminals 303 and 304 may reflect light emitted from the light-emitting device 200 to improve light extraction efficiency and dissipate heat of the light-emitting device 200 to outside.

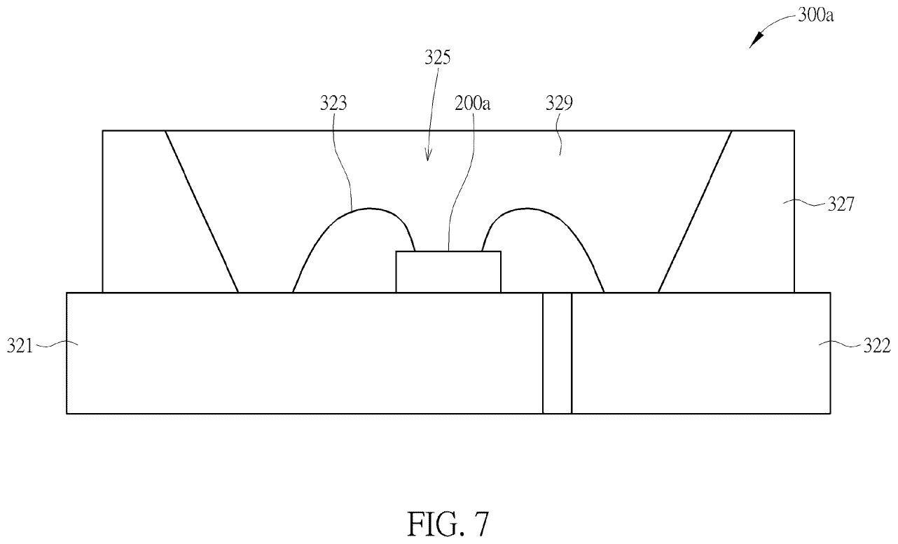

FIG. 7 shows a schematic cross-sectional view of a light-emitting package 300a according to another embodiment of the present disclosure. The light-emitting package 300a includes a encapsulation wall 327, a first terminal 321 and a second terminal 322 connecting to the encapsulation wall 327, a chamber 325 defined by the encapsulation wall 327, the first terminal 321 and the second terminal 322, at least one light-emitting device 200a of FIG. 5, wires 323 and a packaging material 329. In one embodiment, the sidewall of the encapsulation wall may include a reflective structure. In the chamber 325, the first terminal 321 and the second terminal 322 are spaced apart from each other. The light-emitting device 200a is disposed in the chamber 325, and on at least one of the first and second terminals 321 and 322. For example, the light-emitting device 200a may be disposed on the first terminal 321, and the first electrode 210 (shown in FIG. 5) and the second electrode 220 (shown in FIG. 5) of the light-emitting device 200a are electrically connected to the first and second terminals 321 and 322 by the wires 323, respectively. The packaging material 329 is disposed in the chamber 325 and covers the light-emitting device 200a. The packaging material 329 includes, for example, silicon or epoxy resin, and the structure thereof may be single-layer or multi-layer. In one embodiment, the packaging material 329 may further include a wavelength conversion material, such as phosphor and/or a scattering material, for converting the wavelength of the light generated by the light-emitting device 200a.

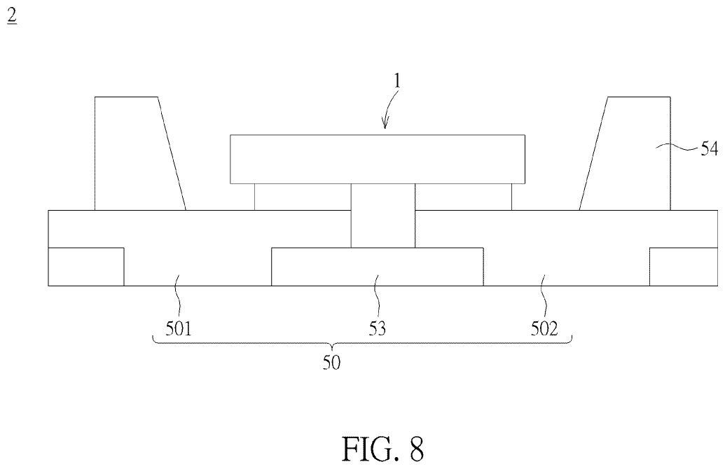

FIG. 8 is a schematic view of a light-emitting apparatus 2 disclosed in an embodiment of the present application. The light-emitting device 1 can be the light-emitting device 200a of FIG. 5, and is mounted on the first terminal 501 and the second terminal 502 of the package substrate 50 in the form of flip-chip. The first terminal 501 and the second terminal 502 are electrically insulated from each other by an insulating portion 53 comprising an insulating material. The main light-extraction surface of the flip-chip is one side of the growth substrates opposite to the surface where the electrode pad formed thereon. For example, the bottom surface of the carrier substrate 202 of the light-emitting device 200a of FIG. 5 is the main light-extraction surface. An encapsulation wall 54 can be provided around the light-emitting device 1. The encapsulation wall 54 may have a reflective inner surface to increase the light extraction efficiency of the light-emitting apparatus 2. In one embodiment, similar to the embodiment of the light-emitting package 300a, the light-emitting apparatus 2 may include a packaging material which is disposed in a chamber defined by the encapsulation wall and covers the light-emitting device 1.

The light-emitting package 300 of FIG. 6, the light-emitting package 300a of FIG. 7 and the light-emitting apparatus 2 of FIG. 8 may be applied to a backlight unit, a lighting unit, a display device, an indicator, a lamp, a street lamp, a lighting device for a vehicle, a display device for a vehicle, or a smart watch, but is not limited thereto.

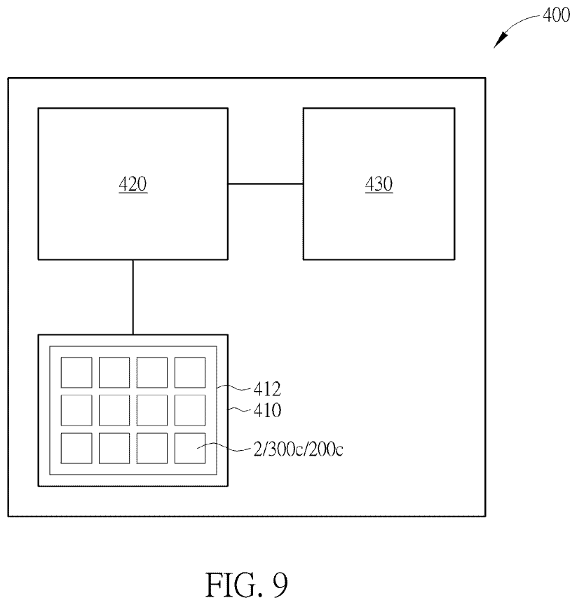

FIG. 9 shows a schematic function block view of a light-emitting system 400 according to an embodiment of the present disclosure. The light-emitting system 400 may be a vehicle light-emitting system and includes a light-emitting apparatus 410, a power module 420 and a control module 430. The power module 420 is connected to the light-emitting apparatus 410. The control module 430 is connected to the power module 420. In one embodiment, the light-emitting apparatus 410 includes a circuit board 412 and a plurality of light-emitting devices 200c disposed on the circuit board 410. The light-emitting devices 200c may be the aforementioned light-emitting devices 200 of FIG. 4 or the light-emitting devices 200a of FIG. 5. In another embodiment, the light-emitting apparatus 410 includes a plurality of light-emitting packages 300c disposed on the circuit board 410. The light-emitting packages 300c may be the aforementioned light-emitting packages 300 of FIG. 6, the light-emitting packages 300a of FIG. 7 or the light-emitting apparatus 2 of FIG. 8. The light-emitting apparatus 410 may be a lighting device, a display device, or a backlight unit in an automobile. The power module 420 may receive input voltages and control signals from the control module 430, and provides driving signals to the light-emitting apparatus 410.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a first semiconductor stack, comprising:
a first first-type semiconductor layer;
a first active region disposed on the first first-type semiconductor layer and having a plurality of first recesses; and
a first second-type semiconductor layer conformally covering the first active region and having a plurality of second recesses corresponding to the plurality of first recesses;
a tunnel junction structure conformally covering the first second-type semiconductor layer and having a plurality of third recesses corresponding to the plurality of second recesses; and
a second semiconductor stack disposed on the tunnel junction structure and comprising:
a second first-type semiconductor layer filling up the plurality of third recesses;
a second active region disposed on the second first-type semiconductor layer; and
a second second-type semiconductor layer disposed on the second active region.

2. The semiconductor structure of claim 1, wherein the second first-type semiconductor layer has a flat surface adjacent to the second active region.

3. The semiconductor structure of claim 1, wherein the first second-type semiconductor layer has a thickness less than 2000Å.

4. The semiconductor structure of claim 1, wherein the first active region comprises a top surface, wherein the plurality of first recesses each has an opening on the top surface and a bottom located in the first active region.

5. The semiconductor structure of claim 1, wherein one of the plurality of first recesses has a V shape in a cross-sectional view.

6. The semiconductor structure of claim 1, wherein the second second-type semiconductor layer has a thickness that is greater than a thickness of the first second-type semiconductor layer.

7. The semiconductor structure of claim 4, wherein the first second-type semiconductor layer comprises a first thickness on the top surface of the first active region and a second thickness in one of the first recesses, wherein a first depth of the first recesses is represented as d1, the first thickness is represented as t1, and the second thickness is represented as t2, wherein d1>t1>t2.

8. The semiconductor structure of claim 7, wherein the tunnel junction structure comprises a third thickness on the top surface of the first active region and a fourth thickness in one of the second recesses, wherein a second depth of the second recesses is represented as d2, the third thickness is represented as t3, and the fourth thickness is represented as t4, wherein d2>t3>t4.

9. The semiconductor structure of claim 1, wherein the second active region has a plurality of fourth recesses.

10. The semiconductor structure of claim 9, wherein a number of the plurality of fourth recesses is less than a number of the plurality of first recesses.

11. The semiconductor structure of claim 9, wherein a depth of one of the plurality of fourth recesses is smaller than or the same as a depth of one of the plurality of first recesses.

12. The semiconductor structure of claim 9, wherein the second second-type semiconductor layer fills up the plurality of fourth recesses and has a flat top surface.

13. A light-emitting device, comprising:
the semiconductor structure of claim 1; and
a first electrode disposed on the first first-type semiconductor layer and electrically connected to the first semiconductor stack.

14. The light-emitting device of claim 13, further comprising:
a conductive substrate, disposed under the second semiconductor layer;
a bonding layer disposed between the conductive substrate and the semiconductor structure;
a barrier layer disposed between the bonding layer and the second semiconductor stack; and
a reflective layer disposed between the barrier layer and the second second-type semiconductor layer.

15. The light-emitting device of claim 14, wherein the plurality of first recesses respectively comprises an opening and a bottom, and the opening is closer to the conductive substrate than the bottom.

16. The light-emitting device of claim 13, wherein the first first-type semiconductor layer has an exposed surface not covered by a stacked structure comprising the first active region, the first second-type semiconductor layer, the tunnel junction structure and the second semiconductor stack,
wherein the first electrode is disposed on the exposed surface, the second electrode is disposed on the second second-type semiconductor layer and electrically connected to the second semiconductor stack; and
wherein the light-emitting device further comprises a second electrode electrically connected to the second semiconductor stack.

17. The light-emitting device of claim 16, further comprising a carrier substrate under the first semiconductor stack, the plurality of first recesses respectively comprises an opening and a bottom, and the bottom is closer to the carrier substrate than the opening.

18. A light-emitting package, comprising:
an encapsulation substrate;
a plurality of external electrodes installed on the encapsulation substrate; and
at least one light-emitting device of claim 13 on the encapsulation substrate and electrically connects to the external electrodes.

19. A light-emitting system, comprising:
a light-emitting apparatus comprising at least one light-emitting package of claim 18;
a power module connected to the light-emitting apparatus; and
a control module connected to the power module,
wherein the power module receives an input voltage and a control signal from the control module, and provides a driving signal to the light-emitting apparatus.

20. A light-emitting system, comprising:
a light-emitting apparatus comprising at least one light-emitting device of claim 13;
a power module connected to the light-emitting apparatus; and
a control module connected to the power module,
wherein the power module receives an input voltage and a control signal from the control module, and provides a driving signal to the light-emitting apparatus.
